(19) United States
(12) Patent Application Publication
(10) Pub. No.: US 2024/0203925 A1
(43) Pub. Date: Jun. 20, 2024

(54) SEMICONDUCTOR PACKAGE AND METHOD FOR MANUFACTURING A SEMICONDUCTOR PACKAGE

(71) Applicant: SERIPHY TECHNOLOGY CORPORATION, HSINCHU COUNTY (TW)

(72) Inventors: TZU-WEI CHIU, HSINCHU COUNTY (TW); CHUN-WEI CHANG, TAIPEI CITY (TW); WEI-CHIH CHEN, TAOYUAN CITY (TW); CHE-YEN HUANG, HSINCHU COUNTY (TW)

(21) Appl. No.: 18/504,205

(22) Filed: Nov. 8, 2023

Related U.S. Application Data
(60) Provisional application No. 63/387,568, filed on Dec. 15, 2022.
(60) Provisional application No. 63/502,742, filed on May 17, 2023.

(51) Int. Cl. H01L 23/00; H01L 23/31; H01L 23/498; H01L 25/065

(52) U.S. Cl. CPC H01L 24/24; H01L 23/3121; H01L 23/3142; H01L 23/49827; H01L 24/16; H01L 24/19; H01L 24/73; H01L 25/0652; H01L 2224/16146; H01L 2224/19; H01L 2224/24147; H01L 2225/06517; H01L 2225/06541; H01L 2924/1437

(57) ABSTRACT

The present application discloses a semiconductor package and a method for manufacturing a semiconductor package. The semiconductor package includes a plurality of bottom dies and a plurality of top dies stacked on the bottom dies with a first RDL in between, thereby embedding more computation power within one semiconductor package and enabling flexible routing between dies. In addition, the top dies and the bottom dies are stacked in a face-to-face manner so the signal paths between the top dies and the bottom dies can be shortened, and thus, the IR drop of the transmission between dies can be reduced.

### CROSS REFERENCE

This application claims the benefit of prior-filed U.S. provisional applications No. 63/387,568, filed on Dec. 15, 2022, and No. 63/502,742, filed on May 17, 2023, which are incorporated by reference in its entirety.

### TECHNICAL FIELD

The present disclosure relates to a semiconductor package, and more particularly, to a semiconductor structure having a die-stacking structure.

### DISCUSSION OF THE BACKGROUND

As the artificial intellectual (AI) models have been applied to more and more fields, a demand for suitable hardware having greater computation capability also raises. Since the AI models usually require large amounts of parallel computing, most of the computation hardware includes multiple cores, which requires large circuit area. Furthermore, to improve the computation efficiency, data sharing and/or data switching among different cores is also desired. However, to enable data sharing and/or data switching, connections between cores can be complicated and require even larger area. Therefore, providing a semiconductor structure that can facilitate greater computation capability within a smaller area has become an issue to be solved.

### SUMMARY

One aspect of the present disclosure provides a semiconductor package. The semiconductor package includes a first molding layer, a plurality of top dies, a first RDL, a plurality of micro bumps, a plurality of bottom dies, a second molding layer, a plurality of conductive pillars, and a second RDL. The top dies are disposed within the first molding layer with respective front-sides exposed from the first molding layer. The first RDL has a first surface contacting the first molding layer and facing the respective front-sides of the plurality of top dies. The micro bumps is disposed on a second surface of the first RDL. The bottom dies are bonded to the plurality of micro bumps with respective front-sides. Each of the plurality of bottom dies includes a plurality of through silicon vias (TSVs). The second molding layer molds the plurality of bottom dies and exposing respective back-sides of the plurality of bottom dies. The conductive pillars is disposed in the second molding layer. The second RDL supports the second molding layer, the plurality of conductive pillars and the plurality of bottom dies.

Another aspect of the present disclosure provides a method for manufacturing a semiconductor package. The method includes receiving a carrier, disposing a plurality of top dies over the carrier with respective front-sides of the plurality of top dies facing away from the carrier, forming a first molding layer over the plurality of top dies, grinding the first molding layer to expose the respective front-sides of the plurality of top dies, forming a first RDL on the first molding layer and the plurality of top dies, forming a plurality of micro bumps on the first RDL, forming a plurality of conductive pillars on the first RDL, and bonding a plurality of bottom dies to the plurality of micro bumps with respective front-sides of the plurality of bottom dies facing the first RDL. Each of the plurality of bottom dies includes a plurality of through silicon vias (TSVs). The method further includes forming a second molding layer over the plurality of bottom dies and the plurality of conductive pillars, grinding the second molding layer to expose the plurality of TSVs and the plurality of conductive pillars, and forming a second RDL on the second molding layer, the plurality of conductive pillars and the plurality of bottom dies.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures.

FIG. 1 shows a semiconductor structure according to one embodiment of the present disclosure.

FIG. 2 shows a flow chart of a method for manufacturing the semiconductor package in FIG. 1.

FIGS. 3A to 3K show the forming process of the semiconductor package in FIG. 1 according to the method in FIG. 2.

FIG. 4 shows a placement of the top dies in FIG. 1 from a top view.

FIG. 5 shows a top view of the top dies and the first RDL in FIG. 1 according to one embodiment of the present disclosure.

FIG. 6 shows a top view of dies and the first RDL in FIG. 1 according to another embodiment of the present disclosure.

FIG. 7 shows a semiconductor package according to another embodiment of the present disclosure.

FIG. 8 shows the placement of the top dies on the first RDL in FIG. 7 according to one embodiment of the present disclosure.

FIG. 9 shows the placement of the bottom dies on the second RDL in FIG. 7 according to one embodiment of the present disclosure.

### DETAILED DESCRIPTION

The following description accompanies drawings, which are incorporated in and constitute a part of this specification, and which illustrate embodiments of the disclosure, but the disclosure is not limited to the embodiments. In addition, the following embodiments can be properly integrated to complete another embodiment.

References to “one embodiment,” “an embodiment,” “exemplary embodiment,” “other embodiments,” “another embodiment,” etc. indicate that the embodiment(s) of the disclosure so described may include a particular feature, structure, or characteristic, but not every embodiment necessarily includes the particular feature, structure, or characteristic. Further, repeated use of the phrase “in the embodiment” does not necessarily refer to the same embodiment, although it may.

In order to make the present disclosure completely comprehensible, detailed steps and structures are provided in the following description. Obviously, implementation of the present disclosure does not limit special details known by persons skilled in the art. In addition, known structures and steps are not described in detail, so as not to unnecessarily limit the present disclosure. Preferred embodiments of the present disclosure will be described below in detail. However, in addition to the detailed description, the present disclosure may also be widely implemented in other embodiments. The scope of the present disclosure is not limited to the detailed description, and is defined by the claims.

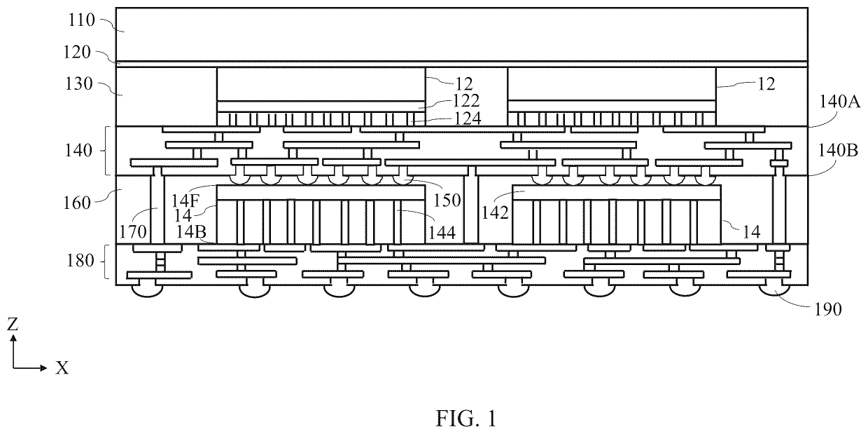

FIG. 1 shows a semiconductor structure 100 according to one embodiment of the present disclosure. The semiconductor structure 100 includes a silicon lid 110, an adhesive layer 120, a first molding layer 130, a plurality of top dies 12, a first redistribution layer (RDL) 140, a plurality of micro bumps 150, a plurality of bottom dies 14, a second molding layer 160, a plurality of conductive pillars 170, a second RDL 180, and a plurality of solder balls 190.

The top dies 12 are disposed within the first molding layer 130 with respective micro pillars 124 at the front-sides 12F exposed from the first molding layer 130. In the present embodiment, the front-sides of the top dies 12 are referred to the sides with the active layer 122 that the transistors and the interconnect structures (not shown) are formed. The first RDL 140 has a first surface 140A contacting the first molding layer 130 and facing the respective front-sides 12F of the top dies 12. The micro bumps 150 are disposed on a second surface 140B of the first RDL 140. The bottom dies 14 are bonded to the micro bumps 150 with respective front-sides 14F in which the active layer 142 are formed. That is, as shown in FIG. 1, the micro bumps 150 can be coupled to the interconnect structures and the transistors (not shown) formed in the active layer 142. In such case, the top dies 12 and the bottom dies 14 can be stacked in a face-to-face manner with the first RDL 140 disposed in between; therefore, the signal paths between the top dies 12 and the bottom dies 14 can be shortened, and the IR drop of the transmission between the top dies 12 and the bottom dies 14 can be reduced.

Also, in the present embodiments, the bottom dies 14 can be powered through a backside power delivery network (BSPDN). In such case, each of the bottom dies 14 may include the active layer 142 and a plurality of through silicon vias (TSVs) 144 within its backside 14B. In the present embodiment, to enable the BSPDN, a thinning process may be performed upon the backsides 14B of the bottom dies 14, so a thickness of the bottom die 14 may be smaller than a thickness of the top die 12. For example, the top die 12 may have a thickness about 200 μm while the bottom die 14 may have a thickness about 10 u m.

The second molding layer 160 is configured to mold the bottom dies 14 and have the respective back-sides 14B of the bottom dies 14 exposed. The second RDL 180 is disposed under the second molding layer 160 and coupled to the exposed TSVs 144. Furthermore, the conductive pillars 170 can be disposed in the second molding layer 160, and both ends of each of the conductive pillars 170 can be exposed from the second molding layer 160 so that the second RDL 180 can be coupled to the first RDL 140 through the conductive pillars 170. In such case, the second RDL 180 would support the second molding layer 160, the conductive pillars 170 and the bottom dies 14.

In some embodiments, each of the plurality of top dies 12 can be a chiplet and may include a computation circuit, and each of the bottom dies 14 may include a static random access memory (SRAM), or a plurality of deep trench capacitors (DTCs). The DTCs may be adopted for forming dynamic random access memories (DRAMs), phase lock loops (PLLs), decoupling circuitries, or other power applications.

Furthermore, in the semiconductor package 100, each of the top dies 12 can be coupled to another top die 12 and at least one bottom die 14 through the first RDL 140. For example, the computation circuits in the top dies 12 may communicate with each other through the signal paths provided by the first RDL 140 laterally. Also, the computation circuits in the top dies 12 may access the SRAM or the DRAM of the bottom dies 14 through the signal paths provided by the first RDL 140 vertically, thereby allowing fast data accessing between the computation circuit and the memories.

Alternatively, each of the bottom dies 14 may have the similar structures and functions as that of the top dies 12. For example, each of the bottom dies 14 may also include a computation circuit as the top dies 12. In such case, the computation circuits in the top dies 12 can also communicate with the computation circuits in the bottom dies 14 through the signal paths provided by the first RDL 140 vertically, thereby integrating even more computation power within one package.

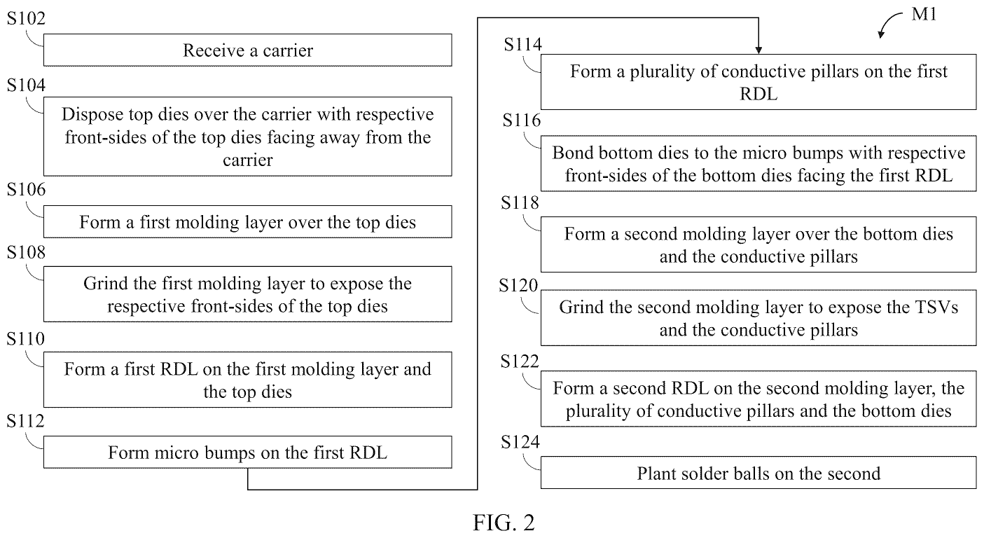

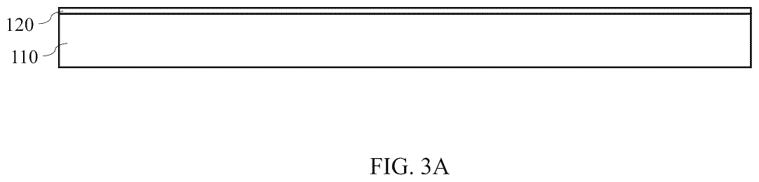

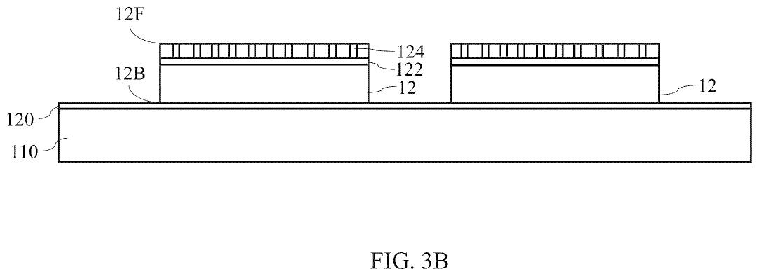

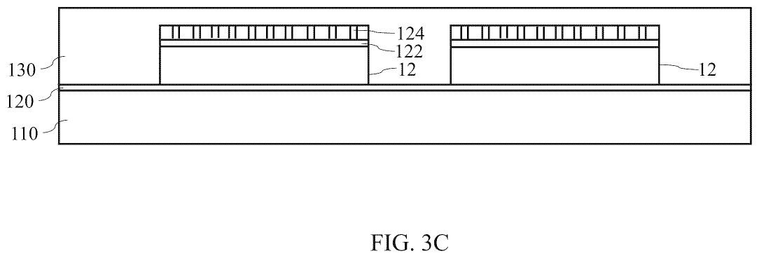

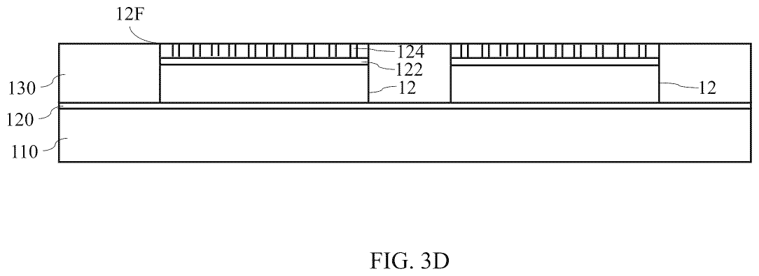

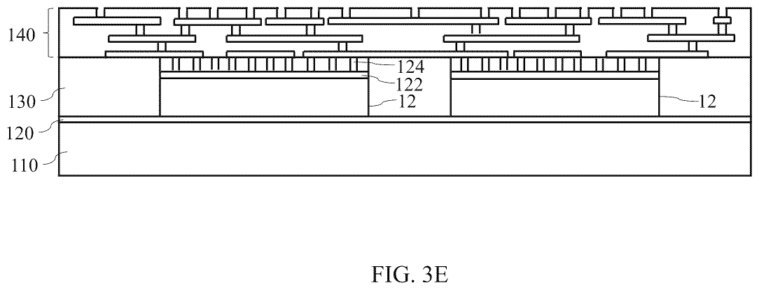

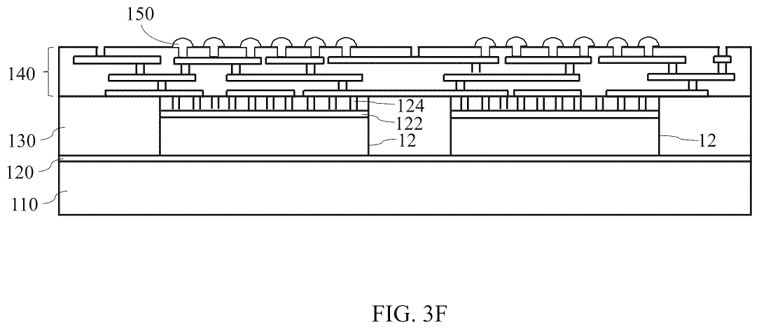

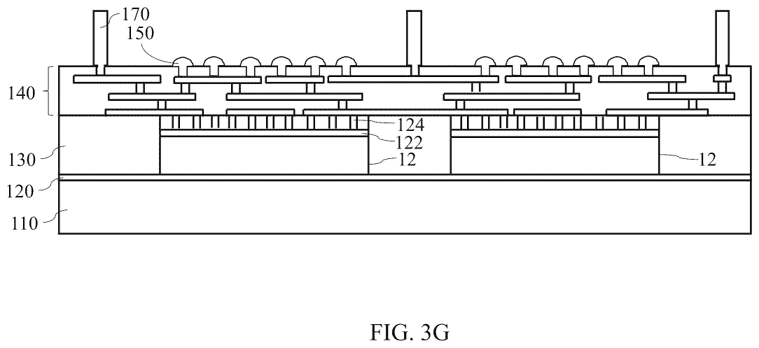

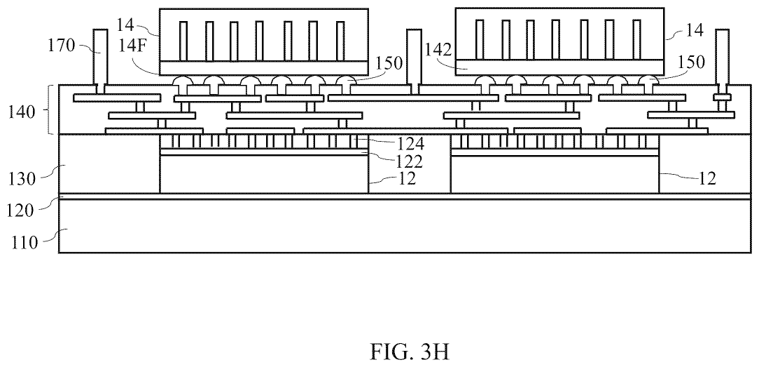

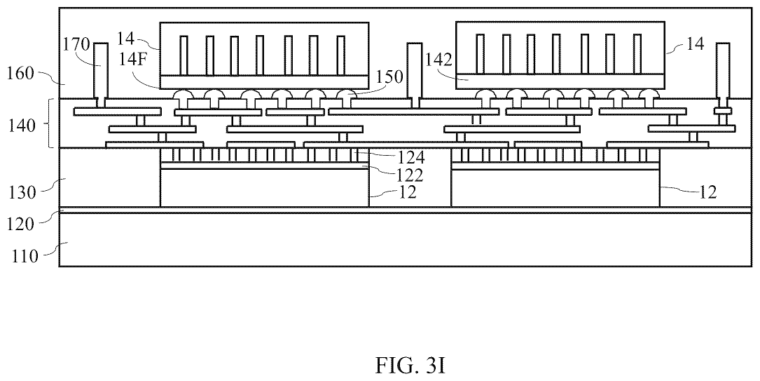

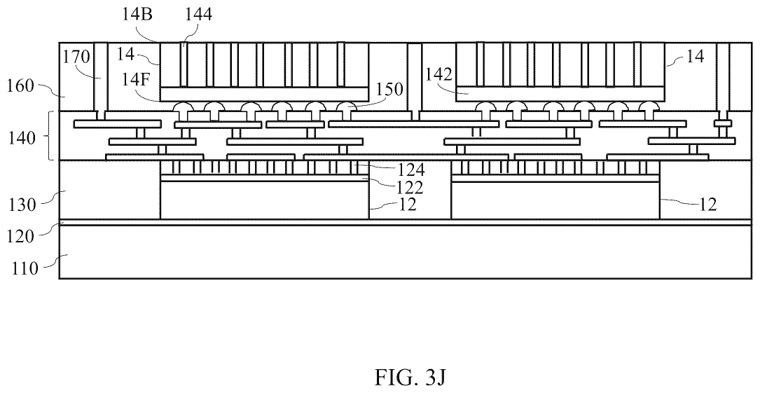

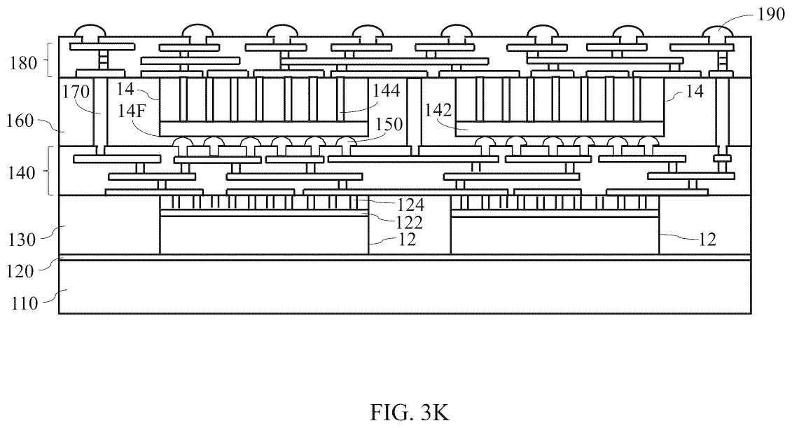

FIG. 2 shows a flow chart of a method M1 for manufacturing the semiconductor package 100. The method M1 includes steps S102 to S124. FIGS. 3A to 3K show the forming process of the semiconductor package 100 according to the method M1.

As shown in FIG. 3A, a carrier 110 is received in step S102. In some embodiments, the carrier 110 can be a silicon wafer, for example, but not limited to, a 300 mm silicon wafer. In addition, as shown in FIG. 3A, the adhesive layer 120 can be applied on the carrier 110 so that the top dies 12 can be disposed and fixed on the carrier 110 in step 104. In some embodiments, the adhesive layer 120 may be a die attach film (DAF) or a thermal interface material (TIM). As shown in FIG. 3B, the top dies 12 can be disposed over the carrier 110 with the respective backside 12B of the top dies 12 attaching to the adhesive layer 120 and the respective front-sides 12F of the top dies 12 facing away from the carrier 110.

Next, in step S106, the first molding layer 130 can be formed over the top dies 12 as shown in FIG. 3C, and in step S108, the first molding layer 130 can be grinded to expose the respective front-sides 12F of the top dies 12 as shown in FIG. 3D.

Afterwards, in step S110, the first RDL 140 can be formed on the first molding layer 130 and the top dies 12 as shown in FIG. 3E. In the present embodiments, openings on the first RDL 140 are formed on the surface so that, in steps S112 and S114, the micro bumps 150 and the conductive pillars 170 can be respectively formed on the first RDL 140 and coupled to the metal lines in the first RDL 140 as shown in FIGS. 3F and 3G. In some embodiment, since the heights of the conductive pillar 170 (e.g., 70 (μm) is greater than the heights of the micro bumps 150 (e.g., 25 (μm), the micro bumps 150 and the conductive pillars 170 are formed in different steps of S112 and S114 sequentially so that the lithography process can be performed with better accuracy. In some embodiments, the conductive pillars 170 can, for example, but not limited to, include copper, aluminum, gold, silver, nickel, tin, platinum, or a combination of the foregoing. Also, the micro bumps 150 can, for example, but not limited to, include copper, gold, nickel, tin or a combination of the foregoing.

In step S116, the bottom dies 14 are bonded to the micro bumps 150 with respective front-sides 14F of the bottom dies 14 facing the first RDL 140 as shown in FIG. 3H, and in step S118, the second molding layer 160 is formed over the bottom dies 14 as shown in FIG. 3I. In some embodiment, the step S118 may include applying an underfill material to fill the spaces between the micro bumps 150 and applying another molding material to mold the underfill material and the bottom dies 14. However, in the present embodiment, step S118 may be performed by one single procedure by using molded underfill (MUF) materials.

After the second molding layer 160 is formed, in step S120, the second molding layer 160 can be grinded to expose the TSVs 144 in the backside 14B of the bottom dies 14 and the conductive pillars 170 as shown in FIG. 3J. Next, in step S122, the second RDL 180 can be formed on the second molding layer 160, the conductive pillars 170 and the bottom dies 14, and then, the solder balls 190 can be further disposed on the second RDL 180 as shown in FIG. 3K. In such case, the second RDL 180 can be coupled to the bottom dies 14 directly, and can be coupled to the top dies 12 through the conductive pillars 170 and the first RDL 140. Therefore, the top dies 12 may receive power through the solder balls 190, the second RDL 180, the conductive pillars 170, and the first RDL 140, whereas the bottom dies 14 may receive power through the solder balls 190, the second RDL 180, and the TSVs 144 formed within the backside 14B of the bottom dies 14.

After the solder balls 190 are planted on the second RDL 180, the carrier 110 can be placed on wafer frame for mechanical sawing so as to dice a plurality of semiconductor packages 100 from the wafer. Finally, the semiconductor package 100 can be soldered to a circuit board through the solder balls 190, and the carrier 110 can be seen as a silicon lid that can also facilitate the thermal dissipation.

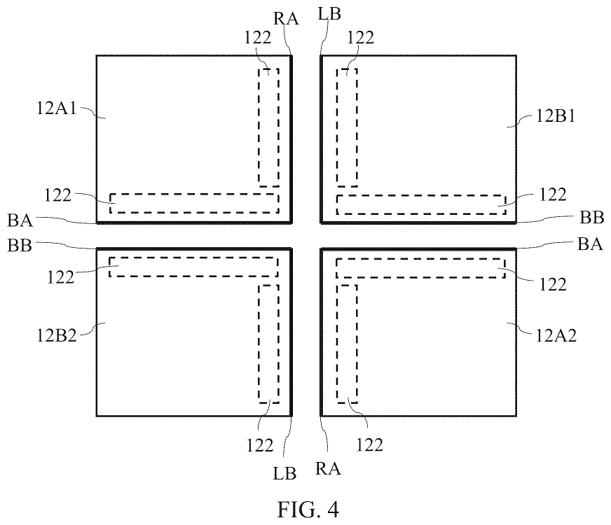

FIG. 4 shows a placement of the top dies 12 from a top view. As shown in FIG. 4, the semiconductor structure 100 includes four top dies 12A1, 12A2, 12B1, and 12B2. The top dies 12A1, 12A2, 12B1, and 12B2 have the same functions but may have different placements of components. In the present embodiment, the four top dies includes two top dies 12A1 and 12A2 of a first type and two top dies 12B1 and 12B2 of a second type. That is, the top dies 12A1 and 12A2 are identical, and can be manufactured with the same set of reticles. Similarly, the top dies 12B1 and 12B2 can be manufactured with another set of reticles.

As shown in FIG. 4, each of the top dies 12A1, 12A2, 12B1, and 12B2 further includes two die-to-die connection circuits disposed along two adjacent edges respectively. For example, each of the top dies 12A1 and 12A2 of the first type has its two die-to-die connection circuits 122 placed along its right edge RA and its bottom edge BA, and each of the top dies 12B1 and 12B2 of the second type has its two die-to-die connection circuits 122 placed along its left edge LB and it bottom edge BB.

In addition, the two top dies 12A1 and 12A2 of the first type and the two top dies 12B1 and 12B2 of the second type are disposed in a staggered manner so that every die-to-die connection circuits 122 of every top die is adjacent to another die-to-die connection circuit 122 of another top die.

Furthermore, the top die 12B2 is rotated by 180 degrees with respect of the top die 12B1 so the die-to-die connection circuit 122 of the top die 12B2 along its bottom edge BB is adjacent to the die-to-die connection circuit 122 of the top die 12A1 along its bottom edge BA. In such case, the die-to-die connection circuit 122 of the top die 12A1 can be coupled to the die-to-die connection circuit 122 of the top die 12B2 with paths provided by the first RDL 140 locally. Similarly, the top die 12A2 is rotated by 180 degrees with respect of the top die 12A1 so the die-to-die connection circuit 122 of the top die 12A2 along its bottom edge BA is adjacent to the die-to-die connection circuit 122 of the top die 12B1 along its bottom edge BB, and the die-to-die connection circuit 122 of the top die 12A2 along its right edge RA is adjacent to the die-to-die connection circuit 122 of the top die 12B2 along its left edge LB. In such case, the die-to-die connection circuit 122 of the top die 12A2 can be coupled to the die-to-die connection circuit 122 of the top die 12B1 and the die-to-die connection circuit 122 of the top die 12B2 with paths provided by the first RDL 140 locally.

Furthermore, in the present embodiment, the die-to-die connection circuit 122 of the top die 12A1 along its right edge RA is adjacent to the die-to-die connection circuit 122 of the top die 12B1 along its left edge LB, so the die-to-die connection circuit 122 of the top die 12A1 can be coupled to the die-to-die connection circuit 122 of the top die 12B1 with paths provided by the first RDL 140 locally. That is, with the staggered arrangement shown in FIG. 4, routing traces between die-to-die connection circuits 122 of the top dies 12A1, 12A2, 12B1, and 12B2 can be shortened.

In addition, in some embodiments, to form the first RDL 140 with the conductive traces for connecting the die-to-die connection circuits 122 of the top dies 12A1, 12A2, 12B1, and 12B2, the reticle stitching technique may be adopted. That is, the step S110 may include performing lithography processes by stitching a plurality of reticles (i.e., the lithography masks). For example, currently, the largest reticle available may have a size about 26 mm×33 mm. In such case, if each of the top dies 12A1, 12A2, 12B1, and 12B2 has a size about half of the size of the largest reticle, then the first RDL 140 may be formed by stitching two reticles having the largest size. In such case, the semiconductor package 100 may have a size about 52 mm×33 mm.

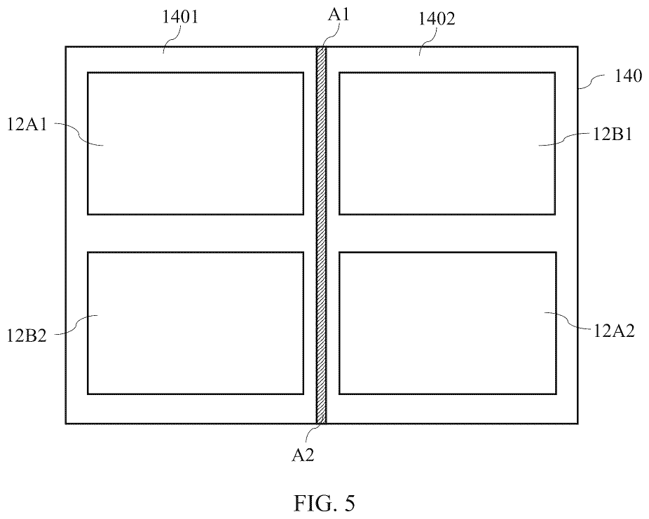

FIG. 5 shows a top view of the top dies 12A1, 12A2, 12B1, and 12B2 and the first RDL 140 formed by stitching reticles according to one embodiment of the present disclosure. As shown in FIG. 5, the first RDL 140 can be formed by using two sets of reticles (masks). For example, the first RDL 140 may include two reticle regions 1401 and 1402 that are formed by two different sets of reticles, and thus, the reticle region 1401 may have an interconnect layout pattern different from an interconnect layout pattern of the reticle region 1402. In the present embodiment, the reticle region 1401 is adjacent to the second reticle region 140. In addition, from a top view, the reticle region 1401 overlaps with the top dies 12A1 and 12B2, and the reticle region 1402 overlaps with the top dies 12B1 and 12A2 as shown in FIG. 5.

Furthermore, in some embodiments, to ensure the traces crossing different reticle regions can be aligned without interrupted, an overlapping region A1 of the reticle region 1401 and an overlapping region A2 of the reticle region 1402 that are overlapping each other may have the same interconnect layout pattern. Also, conductive traces that traverse the boundary between the reticle region 1401 and the reticle region 1402 should traverse the boundary along a perpendicular direction. In addition, to ensure the integrity of the first RDL 140, no vias are allowed in the overlapping regions A1 and A2 of the reticle regions 1401 and 1402.

Due to the respective overlapping regions A1 and A2 in the reticle regions 1401 and 1402, the actual sizes of the semiconductor package 100 may be a bit smaller than the total size of the two reticles. In addition, since the spaces between top dies 12A1, 12A2, 12B1, and 12B2 should be preserved for the conductive traces for connecting the adjacent top dies, the size of the top dies 12A1, 12A2, 12B1, and 12B2 may be smaller than the half size of the reticle.

In some embodiments, the bottom dies 14 may be same as the top dies 12, that is, the bottom dies 14 may also include two type of dies and can be disposed on the second RDL 180 in the same way that the top dies 12 are disposed on the first RDL 140. In such case, the second RDL 180 may also include two reticle regions formed by using two different reticles respectively. Also, from a top view, each of the two reticle regions may overlap two bottom dies 14.

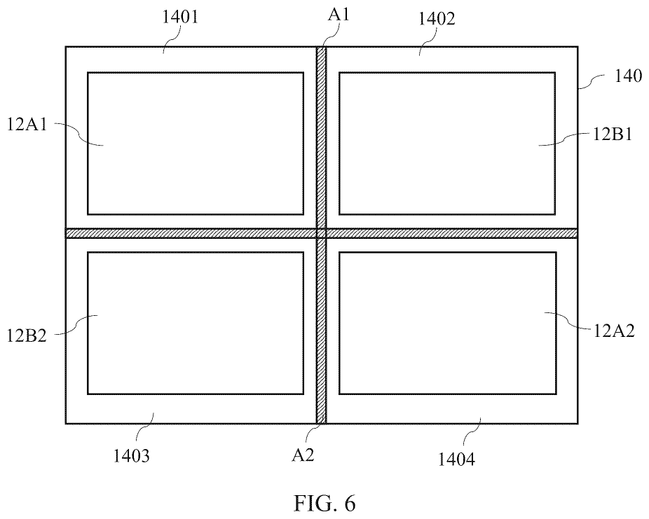

Although the RDLs 140 and 180 can be formed by stitching two reticles in the present embodiment, the present disclosure is not limited thereto. In some other embodiments, the designer may stitching even more reticles if necessary. FIG. 6 shows a top view of dies 12A1, 12A2, 12B1, and 12B2 and the first RDL 140 formed by stitching four reticles according to another embodiment of the present disclosure. As shown in FIG. 6, the dies 12A1, 12A2, 12B1, and 12B2 can have a size about the same as the size of the reticles (e.g., 26 mm×33 mm). In such case, the first RDL 140 can include four reticle regions 1401, 1402, 1403, and 1404 that have different interconnect layout patterns. Also, each of the reticle regions 1401, 1402, 1403, and 1404 may overlap one of the top dies 12A1, 12A2, 12B1, and 12B2 respectively. As a result, the semiconductor package 100 can have a size about 52 mm×66 mm. However, like the embodiment shown in FIG. 5, the reticle regions 1401, 1402, 1403, and 1404 shown in FIG. 6 may also include overlapping regions so as to ensure the integrity of the conductive traces in the first RDL 140.

In the present embodiment, the top dies 12A1, 12A2, 12B1, and 12B2 and the bottom dies 14 may all be chiplets that each includes at least one computation core, so the semiconductor package 100 can integrate greater computation power of multi-core (e.g., 8 cores) within a small area. However, in some embodiments, to further improve the computation power within a limited area, a system on wafer (SoW) can also be achieved within a semiconductor package.

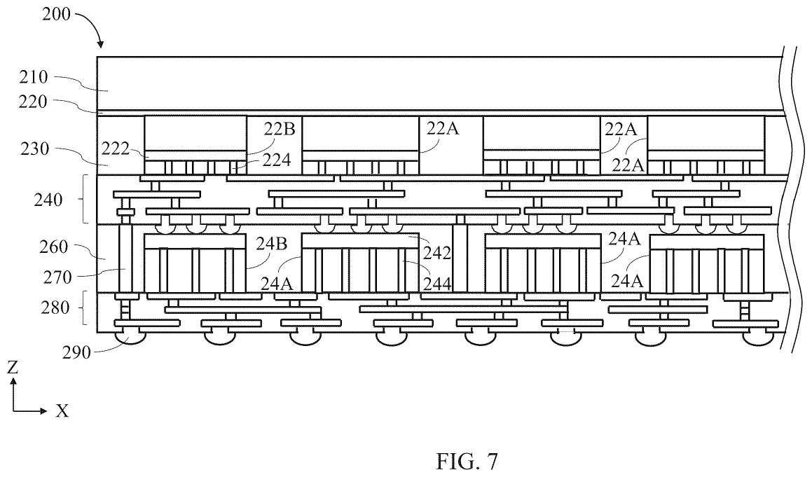

FIG. 7 shows a semiconductor package 200 according to another embodiment of the present disclosure. The semiconductor package 200 have a structure similar to that of the semiconductor package 100. For example, the semiconductor package 200 includes a silicon lid 210, an adhesive layer 220, a first molding layer 230, a first RDL 240, a second molding layer 260, a second RDL 280, and solder balls 290. Furthermore, in the semiconductor package 200, a plurality of top dies 22A and 22B are disposed within the first molding layer 230, and a plurality of bottom dies 24A and 24B are disposed within the second molding layer 260, and the top dies 22A and 22B are stacked on the bottom dies 24A and 24B with the first RDL 240 in between. For example, each of the top dies 22A and 22B can include an active layer 222 coupled to the first RDL 240 through a plurality of micro pillars 224, and each of the bottom dies 24A and 24B can include an active layers 242 coupled to the first RDL 240, and a plurality of TSVs 244 formed in the backsides of the bottom dies 24A and 24B for coupling to the second RDL 280. That is, the semiconductor package 200 also includes a die stacking structure similar to that of the semiconductor package 100, and the top dies 22A and 22B can receive power from the conductive pillars 270 formed in the second molding layer 260.

Therefore, in some embodiments, the semiconductor package 200 may also be manufactured by the method M1 as shown in FIG. 2 and FIGS. 3A to 3K.

However, while the semiconductor package 100 may include four top dies 12 and four bottom dies, the semiconductor package 200 may include more top dies and bottom dies that have different functions. In some embodiments, the semiconductor package 200 can be seen as a system on wafer (SoW). Also, the semiconductor package 200 may have a larger size than the semiconductor package. For example, the size of the semiconductor package 200 can be up to 200 mm×200 mm. In such case, each wafer may be used to form only one or two semiconductor package 200.

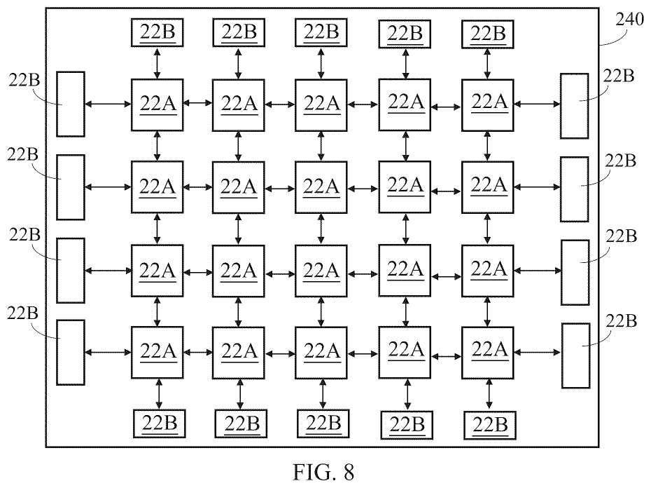

FIG. 8 shows the placement of the top dies 22A and 22B on the first RDL 240 according to one embodiment of the present disclosure. For example, the top dies 22A and 22B includes a plurality of core dies 22A and a plurality of input/output dies 22B. In the present embodiments, each input/output die 22B is coupled to at least one core die 22A through the conductive traces provided by the first RDL 240, and adjacent core dies 22A are coupled to each other through the conductive traces provided by the first RDL 240.

The input/output dies 22B can convert the digital signal generated by the core dies 22A into analog signal and transmit the analog signals to external circuits. Also, the input/output dies 22B can convert the analog signal received from external circuits into digital signals, and transmit the digital signals to the core dies 22A for computation. That is, within the semiconductor package 200, since the signal paths are rather short and stable, the core dies 22A may communicate with each other by analog signals without conversion, thereby achieving fast data sharing among different core dies 22A. In such case, only when the signals are to be transmitted to external or received from external, the digital-to-analog or the analog-to-digital conversion is needed. In the present embodiments, although some of the core dies 22A may not be coupled to the input/output dies 22B directly, such core dies 22A may transmit data to or receive data from the input/output dies 22B through the connections among the core dies 22A.

In the present embodiment, from the top view, the core dies 22A of the top dies can be disposed as an array, and the input/output dies 22B of the top dies can surround the array. Furthermore, to form the first RDL 240 that implements the connection between the core dies 22A and input/output dies 22B, the reticle stitching techniques aforementioned may be applied.

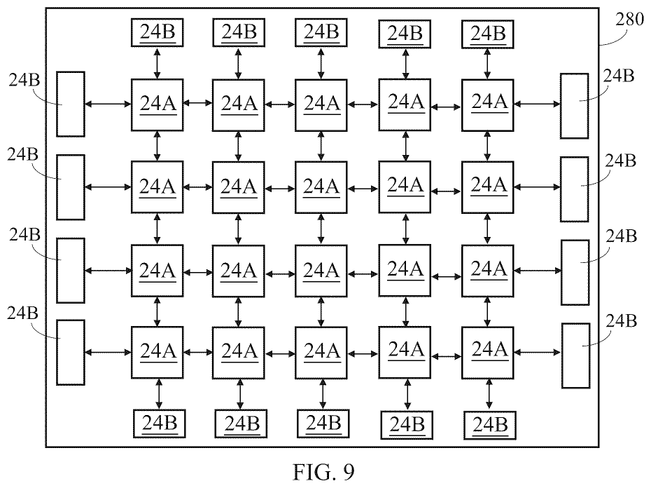

FIG. 9 shows the placement of the bottom dies 24A and 24B on the second RDL 280 according to one embodiment of the present disclosure. Similar to the top dies 22A and 22B shown in FIG. 8, the bottom dies 24A and 24B in the semiconductor package 200 may also include core dies 24A and input/output dies 24B, and may have the same placement as the top dies. That is, the core dies 24A may also be disposed as an array, and the input/output dies 24B can surround the array of the core dies 24A. Also, each input/output die 24B can be coupled to at least one core die 24A through the first RDL 240 and/or the second RDL 280, and adjacent core dies 24A are coupled to each other through the first RDL 240 and/or the second RDL 280. In the present embodiments, although some of the core dies 24A may not be coupled to the input/output dies 24B directly, such core dies 24A may transmit data to or receive data from the input/output dies 24B through the connections among the core dies 24A. Furthermore, in the present disclosure, the top dies 22A may be coupled to adjacent bottom dies 24B through the first RDL 240, thereby allowing data sharing between the top dies 22A and the bottom dies 24B.

In summary, the semiconductor packages and the methods for manufacturing the semiconductor packages provided by the embodiments of the present disclosure allows the designer to embed more computation power within one package. Also, since the top dies and the bottom dies can be coupled through the RDL in between, flexible routing among different dies can be achieved, thereby improving the efficiency of data sharing and/or data access.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods and steps.

What is claimed is:

1. A semiconductor package comprising:
a first molding layer;
a plurality of top dies disposed within the first molding layer with respective front-sides exposed from the first molding layer;
a first RDL having a first surface contacting the first molding layer and facing the respective front-sides of the plurality of top dies;
a plurality of micro bumps disposed on a second surface of the first RDL;
a plurality of bottom dies bonded to the plurality of micro bumps with respective front-sides, wherein each of the plurality of bottom dies comprises a plurality of through silicon vias (TSVs);
a second molding layer molding the plurality of bottom dies and exposing respective back-sides of the plurality of bottom dies;
a plurality of conductive pillars disposed in the second molding layer; and
a second RDL supporting the second molding layer, the plurality of conductive pillars and the plurality of bottom dies.

2. The semiconductor package of claim 1, wherein each of the plurality of top dies comprises a computation circuit, and each of the plurality of bottom dies comprises a computation circuit, a static random access memory (SRAM), or a plurality of deep trench capacitors.

3. The semiconductor package of claim 2, wherein a top die of the plurality of top dies is coupled to another top die of the plurality of top dies through the first RDL, and the top die is coupled to a bottom die of the plurality of bottom dies through the first RDL.

4. The semiconductor package of claim 1, wherein the plurality of top dies receive power through the second RDL, the plurality of conductive pillars, and the first RDL, and the plurality of bottom dies receive power through the second RDL and the plurality of TSVs.

5. The semiconductor package of claim 1, wherein from a top view, the first RDL comprises a first reticle region and a second reticle region adjacent to the first reticle region, wherein the first reticle region has a first interconnect layout pattern different from a second interconnect layout pattern of the second reticle region, the first reticle region overlapping at least one top die of the plurality of top dies, and the second reticle region overlapping at least one top die of the plurality of top dies.

6. The semiconductor package of claim 5, wherein the first RDL comprises a plurality of conductive traces, and from the top view:
the plurality of conductive traces traversing a boundary between the first reticle region and the second reticle region.

7. The semiconductor package of claim 5, wherein from the top view, the first RDL further comprises a third reticle region and a fourth reticle region, wherein:
the third reticle region has a third interconnect layout pattern different from a fourth interconnect layout pattern of the fourth reticle region;
the first, the second, the third, and the fourth interconnect layouts are mutually different; and
the first reticle region is adjacent to the third reticle region, and the second reticle region is adjacent to the fourth reticle region.

8. The semiconductor package of claim 1, wherein the plurality of top dies comprise a plurality of core dies and a plurality of input/output dies, each input/output die of the plurality of top dies is coupled to at least one core die of the plurality of top dies, adjacent core dies of the plurality of top dies are coupled to each other, and from a top view, the core dies of the plurality of top dies are disposed as a first array, and the input/output dies of the plurality of top dies surround the first array.

9. The semiconductor package of claim 8, wherein the plurality of bottom dies comprise a plurality of core dies and a plurality of input/output dies, each input/output die of the plurality of bottom dies is coupled to at least one core die of the plurality of bottom dies, adjacent core dies of the plurality of bottom dies are coupled to each other, and from the top view, the core dies of the plurality of bottom dies are disposed as a second array, and the input/output dies of the plurality of bottom dies surround the second array.

10. The semiconductor package of claim 1, wherein from a top view, the second RDL comprises a fifth reticle region and a sixth reticle region, wherein the fifth reticle region has a fifth interconnect layout pattern different from a sixth interconnect layout pattern of the sixth reticle region, and the fifth reticle region overlapping at least one bottom die of the plurality of bottom dies, and the sixth reticle region overlapping at least one bottom die of the plurality of bottom dies.

11. A method for manufacturing a semiconductor package comprising:
receiving a carrier;
disposing a plurality of top dies over the carrier with respective front-sides of the plurality of top dies facing away from the carrier;
forming a first molding layer over the plurality of top dies;
grinding the first molding layer to expose the respective front-sides of the plurality of top dies;
forming a first RDL on the first molding layer and the plurality of top dies;
forming a plurality of micro bumps on the first RDL;
forming a plurality of conductive pillars on the first RDL;
bonding a plurality of bottom dies to the plurality of micro bumps with respective front-sides of the plurality of bottom dies facing the first RDL, wherein each of the plurality of bottom dies comprises a plurality of through silicon vias (TSVs);
forming a second molding layer over the plurality of bottom dies and the plurality of conductive pillars;
grinding the second molding layer to expose the plurality of TSVs and the plurality of conductive pillars; and
forming a second RDL on the second molding layer, the plurality of conductive pillars and the plurality of bottom dies.

12. The method of claim 11, wherein each of the plurality of top dies comprises a computation circuit, and each of the plurality of bottom dies comprises a computation circuit, a static random access memory (SRAM), or a plurality of deep trench capacitors.

13. The method of claim 12, wherein a top die of the plurality of top dies is coupled to another top die of the plurality of top dies through the first RDL, and the top die is coupled to a bottom die of the plurality of bottom dies through the first RDL.

14. The method of claim 11, wherein the plurality of top dies receive power through the second RDL, the plurality of conductive pillars, and the first RDL, and the plurality of bottom dies receive power through the second RDL and the plurality of TSVs.

15. The method of claim 11, wherein the step of forming the first RDL on the first molding layer and the plurality of top dies comprises:
forming a first reticle region of the first RDL by utilizing a first reticle; and
forming a second reticle regions of the first RDL by utilizing a second reticle different from the first reticle;
wherein the first reticle region is adjacent to the second reticle region, and from a top view, the first reticle region overlaps with at least one top dies of the plurality of top dies, and the second reticle region overlaps with at least one top dies of the plurality of top dies.

16. The method of claim 15, wherein the first RDL comprises a plurality of conductive traces, and from the top view:
the plurality of conductive traces traversing a boundary between the first reticle region and the second reticle region.

17. The method of claim 15, wherein the step of forming the first RDL on the first molding layer and the plurality of top dies comprises:
forming a third reticle region of the first RDL by utilizing a third reticle different from the first reticle and the second reticle; and
forming a fourth reticle region of the first RDL by utilizing a fourth reticle different from the first reticle, the second reticle, and the third reticle.

18. The method of claim 11, wherein the step of disposing a plurality of top dies comprise disposing a plurality of core dies and a plurality of input/output dies, each input/output die of the plurality of top dies is coupled to at least one core die of the plurality of top dies, and adjacent core dies of the plurality of top dies are coupled to each other, and from a top view, the core dies of the plurality of top dies are disposed as a first array, and the input/output dies of the plurality of top dies surround the first array.

19. The method of claim 18, wherein the step of disposing a plurality of bottom dies comprise disposing a plurality of core dies and a plurality of input/output dies, each input/output die of the plurality of bottom dies is coupled to at least one core die of the plurality of bottom dies, and adjacent core dies of the plurality of bottom dies are coupled to each other, and from the top view, the core dies of the plurality of bottom dies are disposed as a second array, and the input/output dies of the plurality of bottom dies surround the second array.

20. The method of claim 11, wherein from a top view, the step of forming a second RDL on the second molding layer, the plurality of conductive pillars and the plurality of bottom dies comprises:
forming a fifth reticle region of the second RDL by utilizing a fifth reticle; and
forming a sixth reticle region of the second RDL by utilizing a sixth reticle different from the fifth reticle;
wherein the fifth reticle region is adjacent to the sixth reticle region, the fifth reticle region overlapping at least one bottom die of the plurality of bottom dies, and the sixth reticle region overlapping at least one bottom die of the plurality of bottom dies.
